(19) United States
(12) Patent Application Publication
(10) Pub. No.: US 2007/0298596 A1
(43) Pub. Date: Dec. 27, 2007

(54) Method of removing a photoresist pattern, method of forming a dual polysilicon layer using the removing method and method of manufacturing a semiconductor device using the removing

(75) Inventors: Keum-Joo Lee, Hwaseong-si (KR); Kyoung-Chul Kim, Suwon-si (KR); Byoung-Yong Gwak, Suwon-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 11/812,147

(22) Filed: Jun. 15, 2007

(30) Foreign Application Priority Data
Jun. 27, 2006 (KR) 10-2006-0058149

(51) Int. Cl. H01L 21/425; H01L 21/8238

(52) U.S. Cl. 438/514; 438/527; 438/532; 438/199

(57) ABSTRACT

In a method of removing a photoresist pattern, a photoresist pattern may be formed on an object layer. Impurities may be implanted into the object layer by a first ion implantation process employing the first photoresist pattern as a first ion implantation mask. The photoresist pattern hardened by the first ion implantation process may be transformed into a first water-soluble photoresist pattern. The water-soluble photoresist pattern may be removed from the object layer.

### PRIORITY STATEMENT

This application claims the benefit of priority under 35 USC § 119 to Korean Patent Application No. 10-2006-0058149, filed on Jun. 27, 2006, in the Korean Intellectual Property Office, the entire contents of which are incorporated herein in their entirety by reference.

### BACKGROUND

1. Field

Example embodiments relate to a method of removing a photoresist pattern, a method of forming a dual polysilicon layer using the removing method, and/or a method of manufacturing a semiconductor device using the removing method. For example, example embodiments relate to a method of removing a photoresist pattern which may reduce organic residues left on an object layer after performing an ion implantation process, a method of forming a dual polysilicon layer using the removing method, and/or a method of manufacturing a semiconductor device using the removing method.

2. Description of Related Art

In a photolithography process included among processes for manufacturing a semiconductor device, after a photoresist composition is coated on a semiconductor substrate, for example, a wafer or other object, to form a photoresist film and the coated photoresist film is exposed to form a photoresist pattern having a desired, or alternatively, a predetermined pattern, a developing solution is provided for the exposed photoresist pattern to develop the photoresist pattern. The photoresist pattern serves as an etching mask in an etching process or as an ion implantation mask in an ion implantation process. The photoresist pattern is removed from the semiconductor substrate or the object after performing the etching process or the ion implantation process. The photoresist pattern may be removed from the semiconductor substrate by a conventional ashing process or a conventional stripping process. However, if the photoresist pattern is removed by a conventional ashing process or a conventional stripping process, an organic residue generated from the photoresist pattern may substantially remain on the substrate. If the photoresist pattern which served as the ion implantation mask in the ion implantation process is removed by a conventional ashing process or a conventional stripping process, the organic residues generated from the photoresist pattern may remain on the substrate, and the organic residues may cause damage to a semiconductor device during subsequent processes.

FIGS. 1 and 2 are cross-sectional views illustrating a conventional ion implantation process employing a conventional photoresist pattern as an ion implantation mask.

Referring to FIG. 1, after an undoped polysilicon layer 10 divided into first and second regions is formed on a substrate 5, a photoresist pattern 15 is formed on the second region of the undoped polysilicon layer 10. The first region of the undoped polysilicon layer 10 into which impurities are to be implanted may be exposed through the photoresist pattern 15.

Impurities are implanted into the exposed first region of the undoped polysilicon layer 10 by an ion implantation process employing the photoresist pattern 15 as an ion implantation mask, as shown by arrows in FIG. 1. The impurities may also be implanted into the photoresist pattern 15 by the ion implantation process. Conditions of the ion implantation process may be controlled such that the impurities may not penetrate the photoresist pattern 15. The impurities may be implanted into the undoped polysilicon layer 10, the photoresist pattern 15, and an interface region between undoped polysilicon layer 10 and the photoresist pattern 15.

Referring to FIG. 2, after a polysilicon layer 30 having a first region 20 where the impurities are implanted and a second region 25 where the impurities are not implanted is formed on the substrate 10 by the ion implantation process, the photoresist pattern 15 is removed from the polysilicon layer 30 by an ashing process and a stripping process. However, during the ion implantation process, the photoresist pattern 15 may be hardened by ion implantation energy or a physical property of the impurities, and water-solubility of the photoresist pattern may be reduced. Therefore, the photoresist pattern 15 may not be as cleanly removed from the polysilicon layer 30 by an ashing process and a stripping process. Accordingly, organic residues 35 generated from the photoresist pattern 15 may remain on the polysilicon layer 30 even though the ashing process and the stripping process are performed. For example, the photoresist pattern 15 is physically and chemically damaged by the impurities having a higher energy or gaseous radicals during the ion implantation process such that the hardened photoresist pattern 15 is more strongly adhered to the polysilicon layer 30 and is not as cleanly removed by the sequential ashing or wet stripping process. The organic residues 35 may contaminate a manufacturing process of the semiconductor device or may serve as particles in a subsequent process which form a minute pattern bridge, thereby causing a fatal defect on the semiconductor device.

### SUMMARY

Example embodiments may provide a method of removing a photoresist pattern which may reduce an organic residue.

Example embodiments may provide a method of forming a dual polysilicon layer including portions having different conductive types using a method of removing a photoresist pattern which may reduce an organic residue.

Example embodiments may provide a method of manufacturing a semiconductor device using a method of removing a photoresist pattern which may reduce an organic residue.

In accordance with an example embodiment, a method of removing a photoresist pattern may include forming the photoresist pattern on an object layer. Impurities may be implanted into the object layer by performing a first ion implantation process employing the photoresist pattern as an ion implantation mask. The photoresist pattern hardened by the ion implantation process may be transformed into a water-soluble photoresist pattern. The water-soluble photoresist pattern may be removed from the object layer.

According to an example embodiment, transforming the photoresist pattern hardened by the ion implantation process into the water-soluble photoresist pattern may include treating the hardened photoresist pattern with ozone and/or water vapor.

According to an example embodiment, transforming the photoresist pattern hardened by the ion implantation process into the water-soluble photoresist pattern may include treating the hardened photoresist pattern with ozone and an alkali material.

According to an example embodiment, transforming the photoresist pattern hardened by the ion implantation process into the water-soluble photoresist pattern may be performed at a temperature of about 90° C. to about 120° C.

According to an example embodiment, the water-soluble photoresist pattern may be removed by an ashing process and/or a stripping process.

According to an example embodiment, the ashing process may be performed using a first gas including an oxygen gas.

According to an example embodiment, the first gas may include at least one of a tetrafluoromethane gas and a sulfur hexafluoride gas.

According to an example embodiment, the stripping process may be performed using a sulfuric acid solution.

In accordance with another example embodiment, there is provided a method of forming a dual polysilicon layer. In the method, a polysilicon layer having first and second regions is formed on a substrate. A first photoresist pattern is formed on the second region. First impurities having a first conductive type are implanted into the first region by a first ion implantation process employing the first photoresist pattern as a first ion implantation mask. The first photoresist pattern hardened by the first ion implantation process is transformed into a first water-soluble photoresist pattern. The first water-soluble photoresist pattern is removed from the polysilicon layer. A second photoresist pattern is formed on the first region of the polysilicon layer. Second impurities having a second conductive type may be implanted into the polysilicon layer by a second ion implantation process employing the second photoresist pattern as a second ion implantation mask. The second photoresist pattern hardened by the second ion implantation process may be transformed into a second water-soluble photoresist pattern. The second water-soluble photoresist pattern may be removed from the polysilicon layer.

According to an example embodiment, transforming the first and second photoresist patterns hardened by the first and second ion implantation processes into first and second water-soluble photoresist patterns, respectively, may include treating the hardened first and second photoresist patterns with ozone and/or at least one of water vapor and an alkali material.

According to an example embodiment, transforming the first and second photoresist patterns hardened by the first and second ion implantation processes into first and second water-soluble photoresist patterns, respectively, may be performed at a temperature of about 90° C. to about 120° C.

According to an example embodiment, the first and second water-soluble photoresist patterns may be removed by an ashing process and/or a stripping process.

According to an example embodiment, the ashing process may be performed using a first gas including an oxygen gas, and/or the stripping process may be performed using a sulfuric acid solution.

According to an example embodiment, the first gas may include at least one of a tetrafluoromethane gas and a sulfur hexafluoride gas.

In accordance with still another example embodiment, there is provided a method of manufacturing a semiconductor device. In the method, a semiconductor substrate is divided into a first region and a second region. A gate insulating layer is formed on the semiconductor substrate. A polysilicon layer is formed on the gate insulating layer. A first photoresist pattern is formed on a first portion of the polysilicon layer located over the first region of the semiconductor substrate. First impurities having a first conductive type are implanted into the first portion of the polysilicon layer by a first ion implantation process employing the first photoresist pattern as a first ion implantation mask. The first photoresist pattern hardened by the first ion implantation process is transformed into a first water-soluble photoresist pattern. The first water-soluble photoresist pattern is removed from the polysilicon layer. A second photoresist pattern is formed on a second portion of the polysilicon layer located over the second region of the semiconductor substrate. Second impurities having a second conductive type may be implanted into the polysilicon layer by performing a second ion implantation process employing the second photoresist pattern as a second ion implantation mask. The second photoresist pattern hardened by the second ion implantation process may be transformed into a second water-soluble photoresist pattern. The second water-soluble photoresist pattern may be removed from the polysilicon layer. A conductive layer may be formed on the polysilicon layer, a mask layer may be formed on the conductive layer, and/or the mask layer, the conductive layer, the polysilicon layer and the gate insulating layer may be patterned to form first and second gate structures having different conductive types on the semiconductor substrate.

According to an example embodiment, transforming the first and second photoresist patterns hardened by the first and second ion implantation processes into the first and second water-soluble photoresist patterns, respectively, may include treating the first and second hardened photoresist patterns with ozone and/or at least one of water vapor and an alkali material.

According to an example embodiment, the first and second water-soluble photoresist patterns may be removed by an ashing process and/or a stripping process.

According to an example embodiment, the first gate structure may include a first gate insulating pattern, a polysilicon layer pattern of the first conductive type, a first conductive layer pattern, and/or a first mask located over the first region of the semiconductor substrate. The second gate structure may include a second gate insulating pattern, a polysilicon layer pattern of the second conductive type, a second conductive layer pattern, and/or a second mask located over the second region of the semiconductor substrate.

According to an example embodiment, the first and second regions may have the second and first conductive types, respectively.

According to an example embodiment, the first and second conductive types may be N-type and P-type, respectively.

According to an example embodiment, the first and second portions may have the second and first conductive types, respectively.

According to an example embodiment, a photoresist pattern hardened by an ion implantation process may be transformed into a water-soluble photoresist pattern by a pre-treatment process using ozone and at least one of water vapor and an alkali material. Therefore, the photoresist pattern may be more cleanly removed by an ashing process and/or a stripping process. If the photoresist pattern is removed, an organic residue generated from the photoresist pattern may be reduced. Accordingly, a defect, for example, a micro-bridge, may not be generated in a semiconductor device so that a yield of the semiconductor device may be improved.

### BRIEF DESCRIPTION OF THE DRAWINGS

The above and/or other aspects and advantages will become more apparent and more readily appreciated from the following detailed description of example embodiments taken in conjunction with the accompanying drawings of which:

FIGS. 1 and 2 are cross-sectional views illustrating a conventional ion implantation process employing a conventional photoresist pattern as an ion implantation mask;

FIGS. 3 to 9 are cross-sectional views illustrating a method of forming a dual polysilicon layer according to an example embodiment;

FIG. 10 is a view illustrating a mechanism explaining how an ozone compound may be obtained from a material included in a first photoresist pattern that is hardened by a pre-treatment process; and

FIGS. 11 to 16 are cross-sectional views illustrating a method of forming a semiconductor device according to an example embodiment.

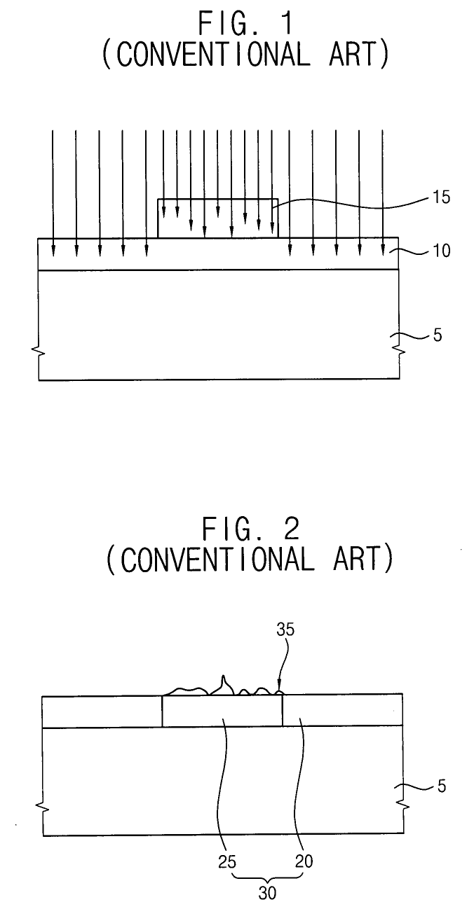

### DETAILED DESCRIPTION OF EXAMPLE EMBODIMENTS

Example embodiments will now be described more fully hereinafter with reference to the accompanying drawings. Embodiments may, however, be embodied in many different forms and should not be construed as limited to the example embodiments set forth herein. Rather, these example embodiments are provided so that this disclosure will be thorough and complete, and will fully convey the scope to those skilled in the art.

It will be understood that when an element or layer is referred to as being “on,” “connected to” and/or “coupled to” another element or layer, the element or layer may be directly on, connected and/or coupled to the other element or layer, or intervening elements or layers may be present. In contrast, when an element is referred to as being “directly on,” “directly connected to” and/or “directly coupled to” another element or layer, no intervening elements or layers are present.

It will also be understood that, although the terms “first,” “second,” etc., may be used herein to describe various elements, components, regions, layers and/or sections, these elements, components, regions, layers and/or sections should not be limited by these terms. Rather, these terms are used merely as a convenience to distinguish one element, component, region, layer and/or section from another element, component, region, layer and/or section. For example, a first element, component, region, layer and/or section could be termed a second element, component, region, layer and/or section without departing from the teachings of example embodiments.

Spatially relative terms, such as “beneath,” “below,” “lower,” “above,” “upper” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented above the other elements or features. The device may be otherwise oriented (rotated 90 degrees or at other orientations) and the spatially relative descriptors used herein interpreted accordingly.

The terminology used herein is for the purpose of describing particular embodiments only and is not intended as limiting of example embodiments As used herein, the singular terms “a,” “an” and “the” are intended to include the plural forms as well, unless the context clearly indicates otherwise. It will be further understood that the terms “includes” and “including” specify the presence of stated features, integers, steps, operations, elements, and/or components, but do not preclude the presence and/or addition of one or more other features, integers, steps, operations, elements, components, and/or groups thereof.

As used herein, the expressions “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C,” and “A, B, and/or C” includes the following meanings: A alone; B alone; C alone; both A and B together; both A and C together; both B and C together; and all three of A, B, and C together. Further, these expressions are open-ended, unless expressly designated to the contrary by their combination with the term “consisting of.” For example, the expression “at least one of A, B, and C” may also include a fourth member, whereas the expression “at least one selected from the group consisting of A, B, and C” does not.

As used herein, the expression “or” is not an “exclusive or” unless it is used in conjunction with the phrase “either.” For example, the expression “A, B, or C” includes A alone; B alone; C alone; both A and B together; both A and C together; both B and C together; and all three of A, B and, C together, whereas the expression “either A, B, or C” means one of A alone, B alone, and C alone, and does not mean any of both A and B together; both A and C together; both B and C together; and all three of A, B and C together.

Unless otherwise defined, all terms (including technical and scientific terms) used herein may have the same meaning as what is commonly understood by one of ordinary skill in the art. It will be further understood that terms, such as those defined in commonly used dictionaries, should be interpreted as having a meaning that is consistent with their meaning in the context of this specification and the relevant art and will not be interpreted in an idealized and/or overly formal sense unless expressly so defined herein.

Example embodiments may be described with reference to cross-sectional illustrations, which are schematic illustrations of example embodiments. As such, variations from the shapes of the illustrations, as a result, for example, of manufacturing techniques and/or tolerances, are to be expected. Thus, example embodiments should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope

Reference will now be made to example embodiments, which are illustrated in the accompanying drawings, wherein like reference numerals refer to the like components throughout.

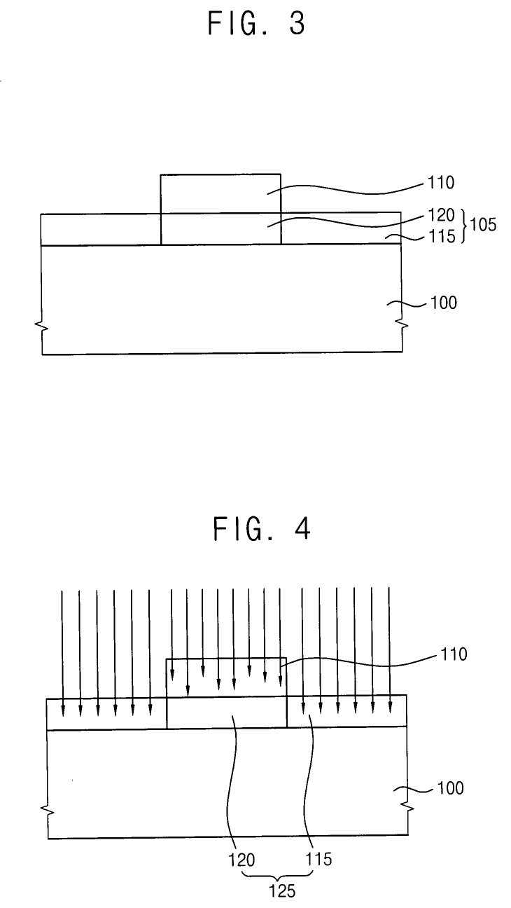

FIGS. 3 to 9 are cross-sectional views illustrating a method of forming a dual polysilicon layer according to an example embodiment.

Referring to FIG. 3, a first preliminary object layer 105 into which impurities are to be implanted by an ion implantation process may be formed on a substrate 100. For example, the first preliminary object layer 105 may include undoped polysilicon or amorphous silicon.

A polysilicon layer doped with impurities may be employed as an electrode or a wire included in a semiconductor device. Accordingly, various methods for implanting impurities into an undoped polysilicon layer have been developed. In a method of forming a dual polysilicon layer including portions having different impurity concentrations, a photoresist pattern may be selectively formed on an undoped polysilicon layer by a photolithography process. Impurities may be implanted into the undoped polysilicon layer using the photoresist pattern as an ion implantation mask. For example, the impurities may be implanted into the undoped polysilicon layer by a plasma doping process (PLDP).

Referring again to FIG. 3, a first photoresist film may be formed on the first preliminary object layer 105. An exposure process and a developing process may be performed on the first photoresist film so that a first photoresist pattern 110 may be formed on the first preliminary object layer 105. A first region 115 of the first preliminary object layer 105 that is to be doped with first impurities may be exposed through the first photoresist pattern 110. A second region 120 of the first preliminary object layer 105 that is to be doped with second impurities may be covered by the first photoresist pattern 110.

Referring to FIG. 4, a first ion implantation process may be performed on the first preliminary object layer 105 using the first photoresist pattern as an ion implantation mask so that first impurities having a first conductive type may be implanted into the first region 115 of the first preliminary object layer 105. Accordingly, a second preliminary object layer 125 including the first region 115 into which the first impurities are doped may be formed on the substrate 100. For example, the first ion implantation process may be a plasma doping process (PLAD). The first impurities may not be implanted into the second region 120 because the second region 120 is covered with the first photoresist pattern 110.

In the first ion implantation process, the first impurities may be implanted into the first photoresist pattern 110 and/or an interface region between the first photoresist pattern 110 and the second preliminary object layer 125. For example, the first impurities having relatively higher energy and/or first gaseous radicals may cause damage to the first photoresist pattern 110. For example, the first impurities having relatively higher energy and the first gaseous radicals may harden the first photoresist pattern 110 and/or degrade solubility, for example, hydrophilic property, water solubility, etc.

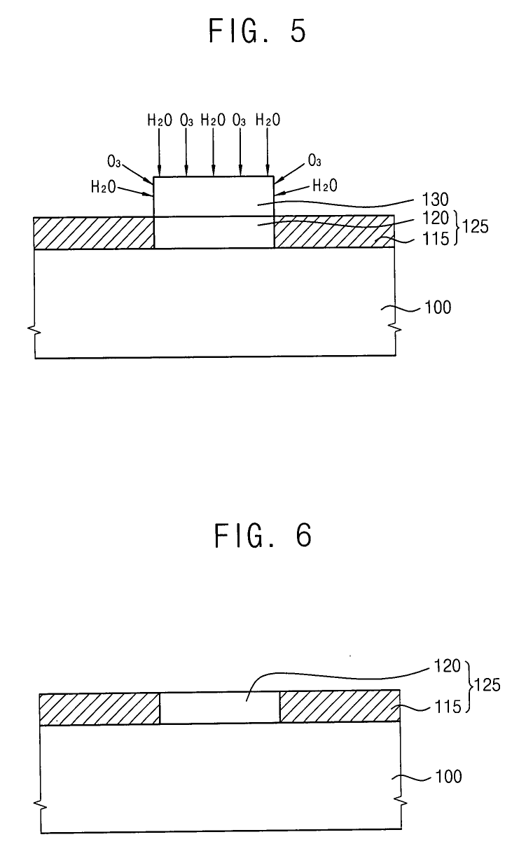

Referring to FIG. 5, a first pre-treatment process may be performed on the hardened first photoresist pattern 110 having a relatively small solubility using ozone (O₃) and water vapor (H₂O). The first pre-treatment process is hereinafter descried in detail.

FIG. 10 is a view illustrating a mechanism explaining how an ozone compound may be obtained from a material included in the first photoresist pattern 110 that is hardened by the first pre-treatment process.

Referring to FIGS. 5 and 10, a material included in the first photoresist pattern 110 may be combined with ozone supplied from the first pre-treatment process so that an ozone compound may be formed. An oxygen ion (O—) and/or a hydroxide ion (OH—) may be generated from the water vapor (H₂O) provided to the photoresist pattern 110. The oxygen ion and the hydroxide ion (OH—) may be combined with the ozone compound to form a water-soluble material. If a temperature at which the chemical reaction occurs increases, an efficiency of the chemical reaction may also increase. The chemical reaction may occur at about 90° C. to about to 120° C. For example, the chemical reaction may occur at a desired, or alternatively, a predetermined temperature corresponding to conditions of a semiconductor manufacturing process. Alternatively, the first pre-treatment may be performed using the ozone gas and/or an alkali material. Accordingly, the first photoresist pattern 110 may be transformed into a first water-soluble photoresist pattern 130 capable of being dissolved in a solution, for example, water. In a case where the hardened first photoresist pattern 110 having the relatively small solubility includes a hydrophobic group of a photosensitive molecule, for example, novolak resin, penol resin, acrylic resin including an aromatic functional group, etc., the hydrophobic group may be reacted with the ozone gas to be transformed into a hydrophilic group during formation of the first water-soluble photoresist pattern 130. The ozone may have a relatively higher reactivity so that the ozone may be activated at a relatively lower temperature. Accordingly, the ozone may be more effectively reacted with a carbon-carbon bond of the hydrophobic group to form an ozonized intermediate. The ozonized intermediate may be chemically unstable so that an oxygen-oxygen bond of the ozonized intermediate may be more easily disconnected. If the oxygen-oxygen bond of the ozonized intermediate is disconnected, the ozone and/or the water vapor may be reacted with the ozonized intermediate to form a carboxyl group. Accordingly, the first water-soluble photoresist pattern 130 including the carboxyl group outwardly exposed may be formed. The first water-soluble photoresist pattern 130 may be soluble in a solvent, for example, water, because the carboxyl group is hydrophilic.

A hardness of the first water-soluble photoresist pattern 130 may be relatively smaller because the first water-soluble photoresist pattern 130 may be formed by the first pre-treatment process using the ozone and the water vapor. Accordingly, the first water-soluble photoresist pattern 130 may be more easily removed from the second preliminary object layer 125 by an ashing process and/or a stripping process. For example, the hardened first photoresist pattern 110 having the relatively smaller solubility may be allowed to have water solubility by performing the pre-treatment process using the ozone gas and/or the water vapor. Accordingly, the first water-soluble photoresist pattern 130 may be more effectively removed and/or a formation of an organic residue may be reduced.

Referring to FIG. 6, the first water-soluble photoresist pattern 130 may be removed from the second preliminary object layer 125, which may be divided into the first region 115 into which the first impurities are implanted and the second region 120 into which the first impurities are not implanted, by a first ashing process and/or a first stripping process.

The first ashing process may be performed using a first gas including an oxygen gas. As an alternative, the first gas may include the oxygen gas and/or a tetrafluoromethane (CF₄) gas. As another alternative, the first gas may include the oxygen gas and/or a sulfur hexafluoride (SF₆) gas. The first ashing process may be performed using a reactive ion etch (RIE) device. Alternatively, the first ashing process may be performed using an induced coupled plasma (ICP) device. The first stripping process may be performed using a sulfuric acid solution. An applied power may be a critical condition for removing the first water-soluble photoresist pattern 130 in the first ashing process. A photoresist pattern used as an etching mask in an etching process may be removed by applying a relatively lower power. On the other hand, a photoresist pattern used as an ion implantation mask in an ion implantation process, for example, a plasma ion doping process performed with relatively higher energy, may be less effectively removed in an ashing process. The photoresist pattern used as an ion implantation mask in an ion implantation process may be less effectively removed because the photoresist pattern may become harder in the ion implantation process. Accordingly, to more effectively remove the photoresist pattern used as the ion implantation mask, a relatively larger power may be required to be applied in the ashing process. However, in a case where the relatively larger power is applied in the ashing process to more effectively remove the photoresist pattern, the photoresist pattern may be hardened in the ashing process. Accordingly, it may be difficult to sufficiently increase the power applied in the ashing process.

Therefore, the hardened first photoresist pattern 110 having the relatively smaller solubility may be transformed into the first water-soluble photoresist pattern 130 by the pre-treatment process. Accordingly, the first water-soluble photoresist pattern 130 may be more cleanly removed without a formation of an organic residue.

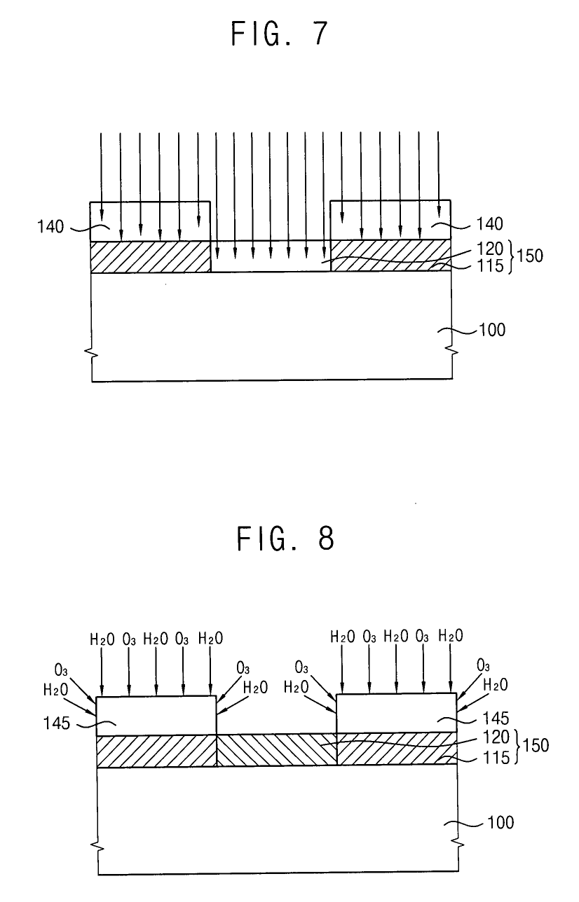

Referring to FIG. 7, a second photoresist film may be formed on the second preliminary object layer 125. An exposure process and a developing process may be performed on the second photoresist film so that a second photoresist pattern 140 may be formed. The second region 120 of the second preliminary object layer 125 into which second impurities are to be implanted may be exposed through the second photoresist pattern 140. On the other hand, the first region 115 of the second preliminary object layer 125 including the first impurities may be covered with the second photoresist pattern 140.

The second impurities having a second conductive type may be implanted into the second region 120 of the second preliminary object layer 125 by a second ion implantation process so that an object layer 150 may be formed. The second photoresist pattern 140 may be used as an ion implantation mask in the second ion implantation process. The object layer 150 may include the first region 115 into which the first impurities are implanted and the second region 120 into which the second impurities are implanted. In a case where the first conductive type of the first impurities is an N-type, the second conductive type of the second impurities may be a P-type. However, the first conductive type of the first impurities may be a P-type, and the second conductive type of the second impurities may be an N-type. The second ion implantation process may be a plasma doping process (PLAD). The second Impurities may not be implanted into the first region 115 of the object layer 150 covered with the second photoresist pattern 140 in the second ion implantation process. As a result, the object layer 150 including the first and second regions 115 and 120 having different conductive types may be formed. For example, the object layer 150 corresponding to a dual polysilicon layer may be formed.

In the second ion implantation process, the second impurities may be implanted into the second region 120 of the object layer 150, the second photoresist pattern 140, and/or an interface region between the second photoresist pattern 140 and the object layer 150. Accordingly, the second impurities having relatively higher energy and/or second gaseous radicals may cause damage to the second photoresist pattern 140. For example, the second impurities having relatively higher energy and/or the second gaseous radicals may harden the second photoresist pattern 140 and/or degrade solubility, for example, hydrophilic property, water solubility, etc.

Referring to FIG. 8, a second pre-treatment process may be performed on the hardened second photoresist pattern 140 having a relatively smaller solubility by using ozone (O₃) and water vapor (H₂O). The second pre-treatment may be substantially similar to the first pre-treatment described in FIG. 10, and, therefore, a detailed description thereof will be omitted. The second pre-treatment process may be performed using the ozone gas and/or an alkali material. Accordingly, the hardened second photoresist pattern 140 having the relatively smaller solubility may be transformed into a second water-soluble photoresist pattern 145 which may be dissolved in a solution, for example, water. Accordingly, the second water-soluble photoresist pattern 145 may be more easily removed from the object layer 150 by a second ashing process and/or a second stripping process which reduces a formation of an organic residue.

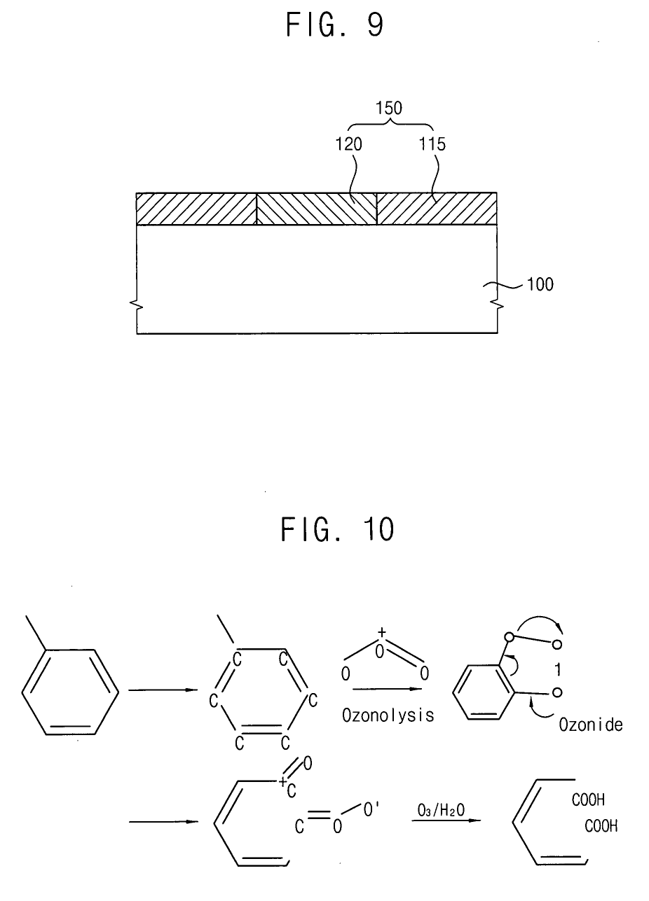

Referring to FIG. 9, the second water-soluble photoresist pattern 145 may be removed from the object layer 150 including the first region having the first impurities and the second region having the second impurities by performing the second ashing process and/or the second stripping process. The second ashing process and the second stripping process may be substantially similar to the first ashing process and the first stripping process, respectively, illustrated in FIG. 10. Accordingly, the object layer 150 including the first and second regions 115 and 120 having different conductive types may be formed on the substrate 100, and/or a formation of an organic residue generated from the first and second photoresist patterns 110 and 140 may be reduced.

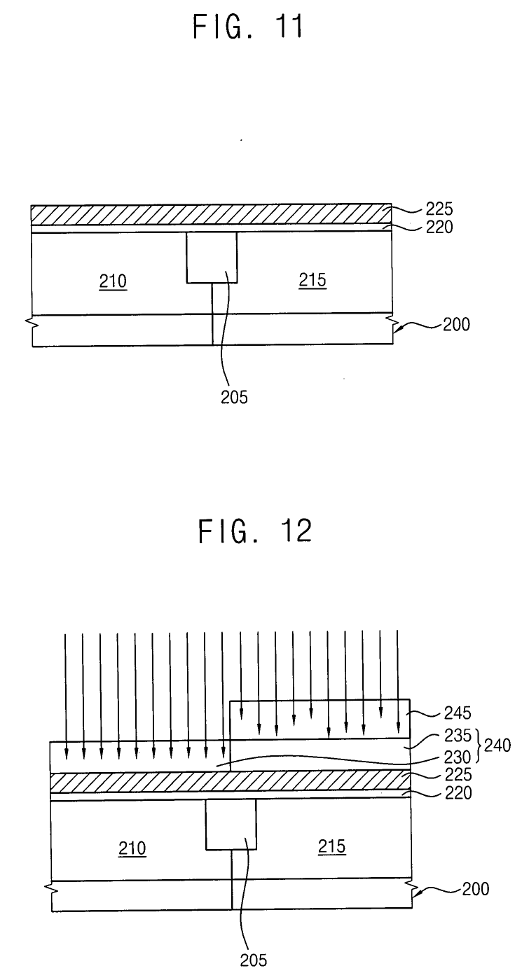

FIGS. 11 to 16 are cross-sectional views illustrating a method of forming a semiconductor device according to an example embodiment.

Referring to FIG. 11, an isolation layer 205 may be formed at a surface of a semiconductor substrate 200. The isolation layer 205 may divide the semiconductor substrate 200 into a first region and a second region. A P-type well 210 and an N-type well 215 may be formed in the first region and the second region, respectively. The semiconductor substrate 200 may be a silicon wafer or a silicon-on-insulator (SOI) substrate. The isolation layer 205 may be formed by a shallow trench isolation (STI) process.

A gate insulating layer 220 may be formed on the semiconductor substrate 200 in which the P-type well 210 the N-type well 215 are formed. The gate insulating layer 220 may be formed using an oxide, for example, silicon oxide. Alternatively, the gate insulating layer 220 may be formed using a metal oxide, for example, hafnium oxide, zirconium oxide, titanium oxide, tantalum oxide, etc.

A first polysilicon layer 225 doped with impurities may be formed on the gate insulating layer 220. The first polysilicon layer 225 may be formed by a low pressure chemical vapor deposition (LPCVD) process. For example, the impurities included in the first polysilicon layer 225 may be N-type impurities or P-type impurities. For example, a type of impurity included in the first polysilicon layer 225 may be determined by a desired, or alternatively, a required property of a semiconductor device.

Referring to FIG. 12, a second preliminary polysilicon layer 240 which is not doped with impurities may be formed on the polysilicon layer 225. For example, the second preliminary polysilicon layer 240 may be formed using a low pressure chemical vapor deposition (LPCVD) process, a chemical vapor deposition (CVD) process, or a plasma-enhanced chemical vapor deposition (PECVD) process. The polysilicon layer 240 may include a first portion 230 and a second portion 235 located on the first region and the second regions, respectively, of the semiconductor substrate 200.

A first photoresist pattern 245 may be formed on the second preliminary polysilicon layer 240. The first region 230 into which first impurities are to be implanted may be exposed through the first photoresist pattern 245. On the other hand, the second region 235 into which second impurities are to be implanted may be covered with the first photoresist pattern 245.

The first impurities having a first conductive type may be implanted into the first portion 230 of the second preliminary polysilicon layer 240 by a first ion implantation process. For example, the first conductive type may be an N-type. The first photoresist pattern 245 may be used as an ion implantation mask in the first ion implantation process, and the first photoresist pattern 245 may be hardened by the first ion implantation process. A solubility of the first photoresist pattern 245 may be reduced by the first ion implantation process.

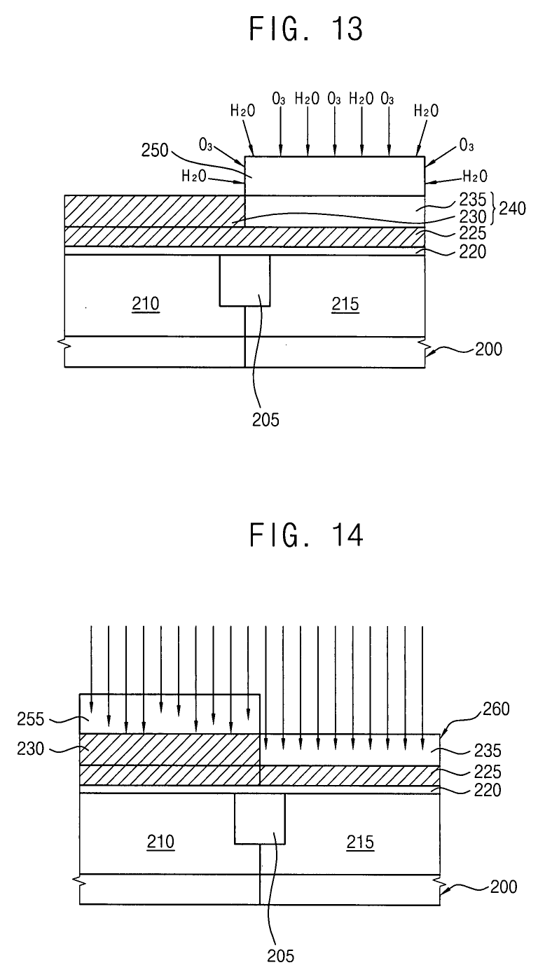

Referring to FIG. 13, the hardened first photoresist pattern 245 may be transformed into a first water-soluble photoresist pattern 250 by a first pre-treatment process. The first pre-treatment process may be substantially similar to the pre-treatment process as illustrated in FIG. 5, and, therefore, a detailed description thereof will be omitted.

The first water-soluble photoresist pattern 250 may be removed from the second preliminary polysilicon layer 240 by a first ashing process and/or a first stripping process. The first ashing process and the first stripping process may be substantially similar to the ashing and stripping process illustrated in FIG. 6, and, therefore, a detailed description thereof will be omitted.

Referring to FIG. 14, a second photoresist pattern 255 covering the first portion 230 of the second preliminary polysilicon layer 240 doped with the first impurities may be formed. The second portion 235 of the second polysilicon layer 240 may be exposed through the second photoresist pattern 255.

Second impurities having a second conductive type may be implanted into the second portion 235 of the second preliminary polysilicon layer 240 by a second ion implantation process so that a second polysilicon layer 260 including the first portion 230 having the first impurities of the first conducive type and the second portion 235 having the second impurities of the second conducive type may be formed. The second photoresist pattern 255 may be used as an ion implantation mask in the second ion implantation process. For example, the second polysilicon layer 260 corresponding to a dual polysilicon layer including portions having different conductive types may be formed on the semiconductor substrate 200. The second photoresist pattern 255 may be hardened by the second ion implantation process. A solubility of the second photoresist pattern 255 may be reduced by the second ion implantation process.

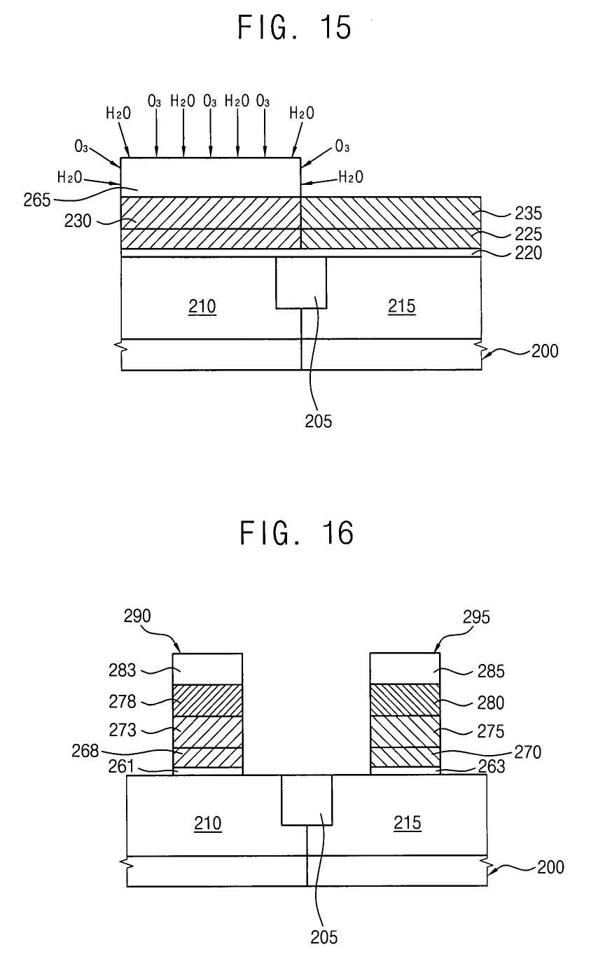

Referring to FIG. 15, the hardened second photoresist pattern 255 having a relatively smaller solubility may be transformed into a second water-soluble photoresist pattern 265 by a second pre-treatment process. The second pre-treatment process may be substantially similar to the pre-treatment process illustrated in FIG. 6, and, therefore, a detailed description thereof will be omitted.

The second water-soluble photoresist pattern 265 may be removed from the second polysilicon layer 260 including the first region 230 and the second region 235 by a second ashing process and/or a second stripping process. The second ashing process and the second stripping process may be substantially similar to the first ashing process and the first stripping process illustrated in FIG. 6, and, therefore, a detailed description thereof will be omitted. Accordingly, if the first and second photoresist patterns 245 and 255 are removed from the second polysilicon layer 260 a formation of an organic residue may be reduced.

Referring to FIG. 16, a conductive layer and a mask layer may be successively formed on the second polysilicon layer 260. The mask layer, the conductive layer, the second polysilicon layer 260, and the gate insulating layer 220 may be patterned, for example, sequentially patterned, to form a first gate structure 290 and a second gate structure 295, respectively, on the first and second regions of the semiconductor substrate 200. The conductive layer may be formed using a metal. The mask layer may be formed using a nitride. The first gate structure 290 may include a first gate insulating pattern 261, a first polysilicon layer pattern 268, a polysilicon layer pattern 273, a first conductive layer pattern 278 and a first mask 283. The polysilicon layer pattern 273 may have the first conductive type. The second gate structure 295 may include a second gate insulating pattern 263, a second polysilicon layer pattern 270, a polysilicon layer pattern 275, a second conductive layer pattern 280 and a second mask 285. The polysilicon layer pattern 275 may have the second conductive type. Accordingly, the first and second gate structures 290 and 295 having different conductive types may be formed on the semiconductor substrate 200.

According to an example embodiment, a photoresist pattern hardened by an ion implantation process may be transformed into a water-soluble photoresist pattern by a pre-treatment process using ozone and/or water vapor or an alkali material. Accordingly, the photoresist pattern may be more cleanly removed by an ashing process and/or a stripping process. If the photoresist pattern is removed, an organic residue generated from the photoresist pattern may be reduced. Accordingly, generation of a defect, for example, a micro-bridge, may be reduced in a semiconductor device, so that a yield of the semiconductor device may be improved.

Although example embodiments have been shown and described in this specification and figures, it would be appreciated by those skilled in the art that changes may be made to the illustrated and/or described example embodiments without departing from their principles and spirit.

What is claimed is:

1. A method of removing a photoresist pattern, the method comprising:
forming a photoresist pattern on a portion of an object layer;
implanting impurities into the object layer by performing an ion implantation process employing the photoresist pattern as a ion implantation mask;
transforming the photoresist pattern hardened by the first ion implantation process into a water-soluble photoresist pattern; and
removing the water-soluble photoresist pattern from the object layer.

2. The method of claim 1, wherein transforming the photoresist pattern hardened by the ion implantation process into the water-soluble photoresist pattern includes treating the hardened photoresist pattern with ozone and water vapor.

3. The method of claim 2, wherein transforming the photoresist pattern hardened by the ion implantation process into the water-soluble photoresist pattern is performed at a temperature of about 90° C. to about 120° C.

4. The method of claim 1, wherein transforming the photoresist pattern hardened by the ion implantation process into the water-soluble photoresist pattern includes treating the hardened photoresist pattern with ozone and an alkali material.

5. The method of claim 4, wherein transforming the photoresist pattern hardened by the ion implantation process into the water-soluble photoresist pattern is performed at a temperature of about 90° C. to about 120° C.

6. The method of claim 1, wherein the water-soluble photoresist pattern is removed by an ashing process and a stripping process.

7. The method of claim 6, wherein the ashing process is performed using a first gas including an oxygen gas.

8. The method of claim 7, wherein the first gas includes at least one of a tetrafluoromethane gas and a sulfur hexafluoride gas.

9. The method of claim 6, wherein the stripping process is performed using a sulfuric acid solution.

10. A method of forming a dual polysilicon layer, the method comprising:
forming a polysilicon layer having a first and second regions on a substrate;
forming a first photoresist pattern on the second region;
implanting first impurities having a first conductive type into the first region by a first ion implantation process employing the first photoresist pattern as a first ion implantation mask; and
transforming the first photoresist pattern hardened by the first ion implantation process into a first water-soluble photoresist pattern;
removing the first water-soluble photoresist pattern from the polysilicon layer;
forming a second photoresist pattern on the second region of the polysilicon layer;
implanting second impurities having a second conductive type into the polysilicon layer by a second ion implantation process employing the second photoresist pattern as a second ion implantation mask;
transforming the second photoresist pattern hardened by the second ion implantation process into a second water-soluble photoresist pattern; and
removing the second water-soluble photoresist pattern from the polysilicon layer.

11. The method of claim 10, wherein transforming the first and second photoresist patterns hardened by the first and second ion implantation processes into first and second water-soluble photoresist patterns, respectively, includes treating the hardened first and second photoresist patterns with ozone and at least one of water vapor and an alkali material.

12. The method of claim 11, wherein transforming the first and second photoresist patterns hardened by the first and second ion implantation processes into first and second water-soluble photoresist patterns, respectively, is performed at a temperature of about 90° C. to about 120° C.

13. The method of claim 10, wherein the first and second water-soluble photoresist patterns are removed by an ashing process and a stripping process.

14. The method of claim 13, wherein
the ashing process is performed using a first gas including an oxygen gas, and
the stripping process is performed using a sulfuric acid solution.

15. The method of claim 13, wherein the first gas includes at least one of a tetrafluoromethane gas and a sulfur hexafluoride gas.

16. A method of manufacturing a semiconductor device, the method comprising:
dividing a semiconductor substrate into a first region and a second region;
forming a gate insulating layer on the semiconductor substrate;
forming a polysilicon layer on a gate insulating layer;
forming a first photoresist pattern on a first portion of the polysilicon layer located over the first region of the semiconductor substrate;
implanting first impurities having a first conductive type into the first portion of the polysilicon layer by performing a first ion implantation process employing the first photoresist pattern as a first ion implantation mask;
transforming the first photoresist pattern hardened by the first ion implantation process into a first water-soluble photoresist pattern;
removing the first water-soluble photoresist pattern from the polysilicon layer;
forming a second photoresist pattern on a second portion of the polysilicon layer;
implanting second impurities having a second conductive type into the polysilicon layer by performing a second ion implantation process employing the second photoresist pattern as a second ion implantation mask;
transforming the second photoresist pattern hardened by the second ion implantation process into a second water-soluble photoresist pattern;
removing the second water-soluble photoresist pattern from the polysilicon layer;
forming a conductive layer on the polysilicon layer;
forming a mask layer on the conductive layer; and
patterning the mask layer, the conductive layer, the polysilicon layer and the gate insulating layer to form first and second gate structures having different conductive types on the semiconductor substrate.

17. The method of claim 16, wherein transforming the first and second photoresist patterns hardened by the first and second ion implantation processes into the first and second water-soluble photoresist patterns, respectively, includes treating the first and second hardened photoresist patterns with ozone and at least one of water vapor and an alkali material.

18. The method of claim 16, wherein the first and second water-soluble photoresist patterns are removed by an ashing process and a stripping process.

19. The method of claim 16, wherein
the first gate structure includes a first gate insulating pattern, a polysilicon layer pattern of the first conductive type, a first conductive layer pattern, and a first mask located over the first region of the semiconductor substrate, and
the second gate structure includes a second gate insulating pattern, a polysilicon layer pattern of the second conductive type, a second conductive layer pattern, and a second mask located over the second region of the semiconductor substrate.

20. The method of claim 16, wherein the first and second regions have the second and first conductive types, respectively.

21. The method of claim 20, wherein the first and second conductive types are N-type and P-type, respectively.

22. The method of claim 16, wherein the first and second portions have the second and first conductive types, respectively.
